(19) United States
(12) Patent Application Publication
(10) Pub. No.: US 2025/0269488 A1
(43) Pub. Date: Aug. 28, 2025

(54) ELECTRICAL CONNECTION FOR CHEMICAL MECHANICAL POLISHING CARRIER HEAD

(71) Applicant: Applied Materials, Inc., Santa Clara, CA (US)

(72) Inventors: Jeonghoon Oh, Saratoga, CA (US); Steven M. Zuniga, Soquel, CA (US); Vladimir Galburt, Campbell, CA (US); Andrew J. Nagengast, Sunnyvale, CA (US); David J. Lischka, Austin, TX (US); Jay Gurusamy, Santa Clara, CA (US); Akshay Aravindan, Sunnyvale, CA (US)

(21) Appl. No.: 18/590,752

(22) Filed: Feb. 28, 2024

(51) Int. Cl. B24B 37/10; B24B 37/32; B24B 49/08; B24B 49/10

(52) U.S. Cl. CPC B24B 37/107; B24B 37/32; B24B 49/08; B24B 49/10

(57) ABSTRACT

A chemical mechanical polishing apparatus has a platen with a top surface to hold a polishing pad, a carrier head to hold a substrate against a polishing surface of the polishing pad during a polishing process, a sensor and/or actuator arranged on the carrier head, and a rotary electrical connection which provides at least two electrical connections between a controller and the sensor and/or actuator. The controller is configured to receive a signal from the sensor and/or actuator and control the carrier head based on the signal.

### TECHNICAL FIELD

The present disclosure relates to chemical mechanical polishing (CMP), and more specifically to a CMP carrier head system having slip ring connections for power and signal.

### BACKGROUND

An integrated circuit is typically formed on a substrate by the sequential deposition of conductive, semiconductive, or insulative layers on a silicon wafer. Planarization of a substrate surface may be required for the removal of a filler layer until a predetermined thickness remains over an underlying layer or an underlying patterned layer is exposed, or to improve planarity for photolithography during fabrication of the integrated circuit.

Chemical mechanical polishing (CMP) is one accepted method of planarization. This planarization method typically requires that the substrate be mounted on a carrier or polishing head. The exposed surface of the substrate is typically placed against a rotating polishing pad. An abrasive polishing slurry is typically supplied to the surface of the polishing pad. The carrier head provides a controllable load on the substrate to push it against the polishing pad. For example, a membrane can be secured to the carrier head with the outer surface of the membrane contacting the substrate and an inner surface of the membrane forming a pressurizable chamber. A pneumatic line through a drive shaft can provide controllable pressure to the chamber.

### SUMMARY

In one aspect, a chemical mechanical polishing apparatus has a platen with a top surface to hold a polishing pad, a carrier head to hold a substrate against a polishing surface of the polishing pad during a polishing process, a sensor and/or actuator arranged on the carrier head, and a rotary electrical connection which provides at least two electrical connections between a controller and the sensor and/or actuator. The controller is configured to receive a signal from the sensor and/or actuator and control the carrier head based on the signal.

In another aspect, a chemical mechanical polishing apparatus has a platen with a top surface to hold a polishing pad, a carrier head to hold a substrate against a polishing surface of the polishing pad during a polishing process, a motor, and a drive shaft connecting the motor to the carrier head to rotate the carrier head. The carrier head includes a membrane that forms a plurality of pressurizable chambers, and a sensor and/or actuator configured arranged on or in the carrier head to generate a signal or receive power. The drive shaft has a central passage and a plurality of outer passages surrounding the central passage. At least two wires pass through the central passage to connect to the sensor and/or actuator, and the plurality of outer passages are in pneumatic connection with the plurality of pressurizable chambers. A rotary pneumatic connector provides a plurality of pneumatic connections between the plurality of outer passage and a plurality of individually controllable pressure sources, and a rotary electrical connector provides at least two electrical connections between the at least two wires in the central passage and a controller.

In another aspect, a chemical mechanical polishing apparatus includes a platen having a top surface to hold a polishing pad, a carrier head to hold a substrate against a polishing surface of the polishing pad during a polishing process, a sensor and/or actuator arranged on or in the carrier head is configured to generate a signal or receive power, a motor, a drive shaft connecting the motor to the carrier head to rotate the carrier head, and a rotary electrical connector. The drive shaft includes a central passage and at least two wires extending through the central passage, and the at least two wires exit the passage through a wall of the drive shaft above the carrier head and are connected to the sensor and/or actuator. The rotary electrical connector provides at least two electrical connections between the at least two wires in the passage and a controller.

Implementations can include, but are not limited to, one or more of the following potential advantages.

Routing electrical cabling through a central passage in the drive shaft can permit the drive shaft to accommodate different cabling needs of different carrier heads. Surrounding the central passage with passages for pneumatic control permits efficient use of the available cross-sectional area. Routing electrical cabling through a side of the draft shaft rather than through an upper housing simplifies construction of the carrier head housing and permits greater flexibility in location of sensors and actuators in the carrier head.

The details of one or more embodiments set forth in the accompanying drawings and the description below. Other features, objects, and advantages will be apparent from the description and drawings, and from the claims.

### BRIEF DESCRIPTION OF THE DRAWINGS

FIG. 1 is a schematic cross-sectional side view of an example polishing apparatus.

FIG. 2 is a schematic cross-sectional side view of a carrier head and drive shaft assembly.

FIG. 3A is a schematic cross-sectional view through a drive shaft at line 3A-3A in FIG. 2.

FIG. 3B is a schematic cross-sectional view through a drive shaft at line 3B-3B in FIG. 2.

Like reference symbols in the various drawings indicate like elements.

### DETAILED DESCRIPTION

Due to ever increasing requirements of precision in semiconductor manufacturing, there is an ever-increasing need for monitoring and precise control of the polishing process. For control, use of electrically driven actuators, e.g., piezoelectric actors or electric motors, within the carrier head has been proposed. For monitoring, placement of sensors on a carrier head has been proposed. However, existing pneumatic connections cannot carry a signal from a metrology sensor located on the carrier head to an external controller. Although wireless connections have been proposed, this necessitates the use of local power, e.g., batteries, which can run out. Moreover, wireless signals can limit the signal bandwidth available to the controller.

One technique to establish a wired electrical connection to the carrier head is to route an electrical wire through a slip ring. However, a single electrical connection is not compatible with most sensors and actuators. Even with multiple electrical connections, there is room for improvement when facing actual implementation challenges, e.g., how to route the wires to permit ease of assembly, adaptability for multiple types of carrier heads with different numbers of sensors and/or actuators, etc.

An approach to address increased needs for direct electrical connections to power sensors and actuators is to use an electrified carrier head system which routes multiple electrical wires to the carrier head through a multi-channel slip ring. The slip ring maintains electrical and signal connections for multiple sensors and/or actuators and allows the carrier head to rotate freely during a polishing process.

The power and signal channels are maintained by an input-output distribution (IOD) block. The IOD block can be placed before, or after, the slip ring, such as directly on the carrier head. The IOD block can be positioned to facilitate process flexibilities such as multiple signal channels can be combined and transmitted via communication connection such as EtherCAT or DeviceNet (Dnet).

The wires can be routed through a central passage in a drive shaft up to the slip ring, and the central passage can be surrounded by multiple other passages for pneumatic control of pressurizable chambers in the carrier head. In addition, the wires can exit the drives shaft before the adapter where the housing of the carrier head is mated to the drive shaft. This reduces the need for complex channels and passages to be formed through the housing itself.

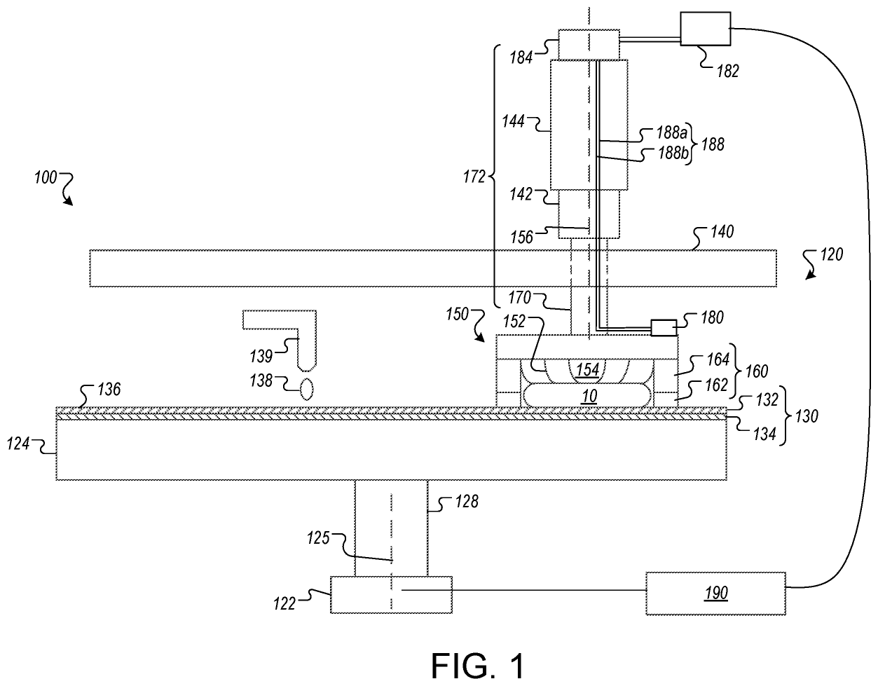

FIG. 1 illustrates an example of a polishing station 120 of a chemical mechanical polishing system 100. The polishing station 120 includes a rotatable disk-shaped platen 124 on which a polishing pad 130 is situated. The platen 124 is operable to rotate about an axis 125. For example, a motor 122 can turn a drive shaft 128 to rotate the platen 124. The polishing pad 130 can be a two-layer polishing pad with an outer polishing layer 134 and a softer backing layer 132.

The polishing station 120 can include a supply port, e.g., at the end of a slurry supply arm 139, to dispense a polishing liquid 138, such as an abrasive slurry, onto the polishing pad 130.

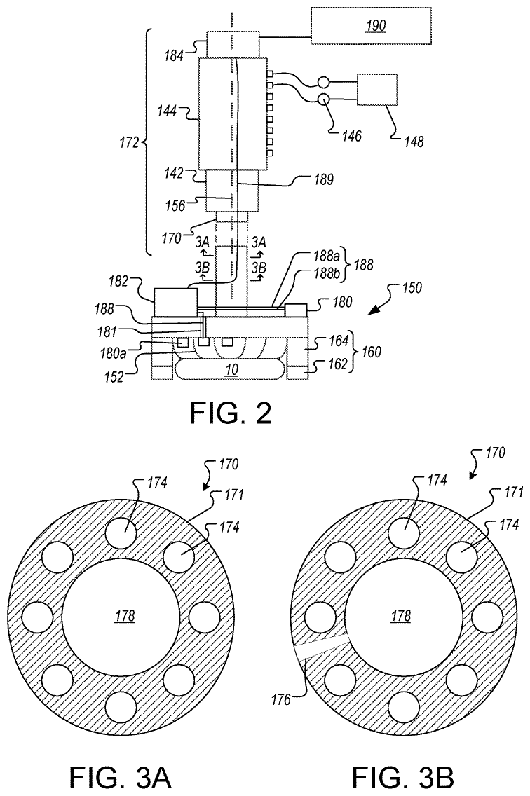

Referring to FIGS. 1 and 2, a carrier head 150 is operable to hold a substrate 110 against the polishing pad 130. The carrier head 150 can include a flexible membrane 152 having a substrate mounting surface to contact the back side of the substrate 110, and a plurality of pressurizable chambers 154 to apply different pressures to different zones, e.g., different radial zones, on the substrate 110. The carrier head 150 can include a retaining ring 160 to hold the substrate below the membrane 152. In some implementations, the retaining ring 160 may include a lower plastic portion 162 that contacts the polishing pad, and an upper portion 164 of a harder material.

In operation, the platen is rotated about its central axis 125, and the carrier head is rotated about its central axis 156 and translated laterally across the top surface of the polishing pad 130.

The carrier head 150 is suspended from a support structure 140, e.g., a carousel or a track, and is connected by a drive shaft 170 to a carrier head rotation motor 142 so that the carrier head can rotate about the axis 156. Optionally, the carrier head 150 can oscillate laterally, e.g., on sliders on the carousel, by movement along the track, or by rotational oscillation of the carousel itself.

A representative sensor 180 is shown affixed to an upper surface of the carrier head 150. Examples of the sensor 180 include an optical sensor, an accelerometer, or a position sensor. The sensor 180 receives power and generates a signal based on the type of sensor.

An input-output distribution (IOD) block 182 which provides electrical communication between the sensor 180 and the controller 190. The IOD block 182 provides power, signal communication, or both, to the sensor 180. The sensor 180 is connected to input-output distribution (IOD) block by one or more wired connections 188, e.g., a power line 188a and a ground line, that pass through a rotary electrical connection 184

In some implementations, as shown in FIG. 1, the IOD block 182 is a stationary part (i.e., not rotating with the carrier head 150). The IOD block 182 connects to the rotary electrical connection 184 which provides electrical connections through the rotary pneumatic connection 144 and the motor 142 to the carrier head 150, e.g., to the sensor 180. In particular, the sensor 180 can be connected to input-output distribution (IOD) block by one or more wired connections 188, e.g., a power line 188a and a ground line, that pass through the rotary electrical connection 184

In some implementations, as shown in FIG. 2, the IOD block 182 is arranged on the carrier head 150 and the rotary electrical connection 184 provides electrical connection between the controller 190 and IOD block 182 through the drive assembly 172. In particular, although FIG. 2 illustrates a single line 189 connecting the input-output distribution (IOD) block 182 to the controller 190, this can be Ethernet-compatible wiring, e.g., an Ethernet cable with five separate wires.

The rotary electrical connection 184 is a slip ring which maintains individual power and signal connections while revolving around the central axis 156. Examples of the rotary electrical connection 184 include a drum-type, or a pancake-type slip ring.

Although the carrier head could have a single sensor or actuator, FIG. 2 illustrates multiple sensors or actuators 180a in the carrier head 150. Having an IOD block 182 on the carrier head 150 permits multiplexing of signals to or from the sensors and/or actuators, thus reducing the number of electrical connections needed in the rotary electrical connection 184. That is, the number of sensors and/or actuators can be larger than the number of electrical connections. This permits a large number of sensors and/or actuators, e.g., ten to a hundred.

Multiple pneumatic connections extend through the drive shaft 170 to connect the pressurizable chambers 154 to a rotary pneumatic connection 144. The rotary pneumatic connection 144 is a multi-channel pneumatic interface having connectors through which individually pressurizable connections extend to individual pressure control valves 146 and a gas pressure source 148.

The electrical and pneumatic connections are housed within the drive shaft 170 in separate channels. The drive shaft 170 enclosing the electrical and pneumatic routing channels simplifies the drive assembly 172 and the associated connections between different carrier heads having different numbers of pressurizable chambers thereby permitting uniformity when utilizing different carrier heads. In such examples, the drive assembly 172, e.g., the drive shaft 170, is useful with the different carrier heads facilitating interchanging different carrier heads between substrates, or processes.

FIGS. 3A and 3B show cross sections of the drive shaft 170 at two different planes shown in FIG. 2. The drive shaft 170 includes outer passages 174 which carry pressurized gas from the individual pressure control valves 146 to the individual pressurizable chambers 154 of the carrier head 150. The outer passages 174 can be evenly spaced around the central axis of the drive shaft 170. The number of passages 174 can be equal to or greater than the number of pressurizable chambers 154 in the membrane 152, e.g., some of the passages 174 may not be used by a particular carrier head 150.

The drive shaft 170 includes a central channel 178 which carries the electrical connections between the rotary electrical connection 184 and the electrical components on the carrier head 150, such as the IOD block 182, or the sensor 180. The central channel 178 is surrounded by the outer passages 174.

FIG. 3B includes a port 176 through a wall 171 of the drive shaft 170 through which the wired electrical connection from the rotary electrical connection 184 to the IOD block 182 passes. Passing the electrical connection through the port 176 enables a wired connection between the rotary electrical connection 184 and the IOD block 182 which increases available power and signal bandwidth between these components. The carrier head 150 and drive assembly 172 are easier to manufacture having wires on the outer surfaces of the carrier head 150, e.g., the top, as space within the carrier head 150 is minimal.

As the drive shaft 170 rotates, the port 176, IOD block 182, and wired connection remain in the same rotating reference frame. Such a configuration can be lower cost to assemble than having the wires run through an adapter that connects the drive shaft to the housing of the carrier head. The port 176 is described with reference to the arrangement of FIG. 2 in which the IOD block 182 is on the carrier head 150, though the same structures, e.g., the passages 174, channel 178, and port 176, are applicable to the arrangement of FIG. 1, in which the rotary electrical connection 184 is between the sensor 180 and the IOD block 182. In addition, although only two sensors 180 are illustrated, there could be more sensors and/or actuators.

In examples in which the sensor 180 is arranged inside the carrier head 150, it is similarly simpler and more cost effective for manufacturing and servicing to run a through-hole 181 from a point on the outside of the carrier head 150 housing than run the wire 188 through the inside of the carrier head 150. For example, if an operator desires to remove the carrier head 150 from the drive shaft 170, it can be simpler to disconnect an electrical connection that is made outside the carrier head, e.g., the connection between cable 189 and the IOD block 182, before the carrier head 150 is removed from the drive shaft 170 (if wiring runs inside the carrier head into the drive shaft, then it may be necessary to remove and hold the carrier head below the drive shaft to access the wires).

A carrier head 151 having the sensor 180 installed within a housing 158 is shown in FIG. 2. The housing 158 includes an opening 186 through which the electrical connection between the IOD block 182 and the sensor 180 transits.

Embodiments of the invention and all the functional operations described in this specification can be implemented in digital electronic circuitry, or in computer software, firmware, or hardware, including the structural means disclosed in this specification and structural equivalents thereof, or in combinations of them. Embodiments of the invention can be implemented as one or more computer program products, i.e., one or more computer programs tangibly embodied in a non-transitory machine-readable storage media, for execution by, or to control the operation of, data processing apparatus, e.g., a programmable processor, a computer, or multiple processors or computers.

Terms of relative positioning are used to denote positioning of components of the system relative to each other, not necessarily with respect to gravity; it should be understood that the polishing surface and substrate can be held in a vertical orientation or some other orientations.

A number of implementations have been described. Nevertheless, it will be understood that various modifications may be made. Accordingly, other implementations are within the scope of the claims.

What is claimed is:

1. A chemical mechanical polishing apparatus comprising:
a platen having a top surface to hold a polishing pad;
a carrier head to hold a substrate against a polishing surface of the polishing pad during a polishing process;
a sensor and/or actuator arranged on the carrier head;
a rotary electrical connection which provides at least two electrical connections between a controller and the sensor and/or actuator, the controller configured to receive a signal from the sensor and/or actuator and control the carrier head based on the signal.

2. The apparatus of claim 1, wherein the rotary electrical connection is a multi-channel rotary electrical connection.

3. The apparatus of claim 1, comprising an input-output distribution (IOD) block, connected to the controller and to the rotary electrical connection.

4. The apparatus of claim 3, wherein the IOD block is connected between the carrier head and the rotary electrical connection.

5. The apparatus of claim 4, wherein the IOD block is mounted on the carrier head.

6. The apparatus of claim 5, wherein the IOD block is mounted on an outside surface of the carrier head.

7. The apparatus of claim 4, comprising a plurality of sensors in the carrier head, and a plurality of wires connecting the plurality of sensors to the IOD block.

8. The apparatus of claim 3, comprising wherein the IOD block is connected between the rotary electrical connection and the controller.

9. The apparatus of claim 1, wherein the carrier head includes a plurality of pressurizable chambers, and the apparatus comprises a drive shaft connecting a motor to the carrier head to rotate the carrier head, the drive shaft including a central passage and a plurality of outer passages surrounding the central passage, wherein at least two wires pass through the central passage to connect to the sensor and/or actuator, and the plurality of outer passages are in pneumatic connection with the plurality of pressurizable chambers.

10. The apparatus of claim 9, wherein the at least two wires exit the passage through a wall of the drive shaft above the carrier head.

11. A chemical mechanical polishing apparatus comprising:
a platen having a top surface to hold a polishing pad;
a carrier head to hold a substrate against a polishing surface of the polishing pad during a polishing process, the carrier head including a membrane that forms a plurality of pressurizable chambers, the carrier head further including a sensor and/or actuator configured to generate a signal or receive power, the sensor and/or actuator arranged on or in the carrier head;
a motor;
a drive shaft connecting the motor to the carrier head to rotate the carrier head, the drive shaft including a central passage and a plurality of outer passages surrounding the central passage, wherein at least two wires pass through the central passage to connect to the sensor and/or actuator, and the plurality of outer passages are in pneumatic connection with the plurality of pressurizable chambers;
a rotary pneumatic connector which provides a plurality of pneumatic connections between the plurality of outer passage and a plurality of individually controllable pressure sources; and
a rotary electrical connector which provides at least two electrical connections between the at least two wires in the central passage and a controller.

12. The apparatus of claim 11, wherein the rotary electrical connector comprises an electrical slip ring.

13. The apparatus of claim 12, wherein the rotary pneumatic connector is positioned between the rotary electrical connector and the carrier head.

14. The apparatus of claim 13, wherein the rotary pneumatic connector is positioned between the rotary electrical connector and the motor.

15. A chemical mechanical polishing apparatus comprising:
a platen having a top surface to hold a polishing pad;
a carrier head to hold a substrate against a polishing surface of the polishing pad during a polishing process, the carrier head further including a sensor and/or actuator configured to generate a signal or receive power, the sensor and/or actuator arranged on or in the carrier head;
a motor;
a drive shaft connecting the motor to the carrier head to rotate the carrier head, the drive shaft including a central passage and at least two wires extending through the central passage, wherein the at least two wires exit the passage through a wall of the drive shaft above the carrier head and are connected to the sensor and/or actuator;
a rotary electrical connector which provides at least two electrical connections between the at least two wires in the passage and a controller.

16. The apparatus of claim 15, wherein the carrier head comprises a housing, the sensor and/or actuator is arranged within the housing, and the housing includes an opening through which one of the wires extends through to connect to the sensor.

17. The apparatus of claim 15, wherein the carrier head includes a plurality of pressurizable chambers, and the apparatus comprises a drive shaft connecting a motor to the carrier head to rotate the carrier head, the drive shaft including a central passage and a plurality of outer passages surrounding the central passage, wherein the at least two wires pass through the central passage to connect to the sensor and/or actuator, and the plurality of outer passages are in pneumatic connection with the plurality of pressurizable chambers.

18. The apparatus of claim 17, comprising an aperture extending through the wall of the drive shaft and passing between two of the plurality of outer passages to the central passage, and wherein the at least two wires pass through the aperture.
